(19) United States
(12) Patent Application Publication
(10) Pub. No.: US 2010/0266455 A1
(43) Pub. Date: Oct. 21, 2010

(54) DEVICE AND A METHOD FOR PROMOTING CRYSTALLISATION

(75) Inventor: Morten SOMMER, Boston, MA (US)

Correspondence Address: BUCHANAN, INGERSOLL & ROONEY PC, POST OFFICE BOX 1404, ALEXANDRIA, VA, 22313-1404, US

(73) Assignee: Microlytic Aps, Roskilde (DK)

(21) Appl. No.: 12/761,037

(22) Filed: Apr. 15, 2010

Related U.S. Application Data
(60) Provisional application No. 61/169,987, filed on Apr. 16, 2009.

(51) Int. Cl. B01L 3/00; B81B 1/00; B32B 37/00

(52) U.S. Cl. 422/100; 156/69; 156/272.2; 29/890.09

(57) ABSTRACT

A method of producing a microfluidic device for promoting target molecule crystallization growth for example for growth of macromolecules such as proteins, nucleic acids and/or carbohydrates Also, a microfluidic device for promoting crystallization of a target molecule from a solution of said target molecule and a liquid precipitant.

### TECHNICAL FIELD

The invention relates to a method of producing a microfluidic device for promoting target molecule crystallization growth for example for growth of macromolecules such as proteins, nucleic acids and/or carbohydrates The invention also relates to a microfluidic device for promoting crystallization of a target molecule from a solution of said target molecule and a liquid precipitant.

### BACKGROUND ART

Crystallization of molecules, such as macromolecules, is an important technique for the biochemistry art. Biochemical molecules, such as nucleic acids, proteins and carbohydrates have unpredictable crystallization structures, and often the 3D structure of the crystallized molecules plays an important role for their biological functions. To get detailed knowledge about the way a protein functions it is critical to determine the three dimensional structure of the protein, since 3D structure and function are very tightly coupled. When biological processes need to be manipulated, the 3D structure is particularly useful, which is seen in medical research. Today more that 90% of the drugs on the market are small ligands that interact with a protein. To understand this interaction and to exploit it in the creation of new and improved drugs, the 3D structure of the ligand-protein complex has to be determined.

Crystallization of molecules e.g. macromolecules, such as proteins is performed by providing a solution of the target compound, and altering the chemical environment of the dissolved target compound such that the target becomes less soluble and reverts to its solid form in crystalline form. This change in chemical environment is typically accomplished by introducing a precipitant that makes the target compound less soluble.

The prior art discloses several methods and crystallization devices for promoting crystallization of macromolecules e.g. for screening such molecules. Three main groups of methods for promoting crystallization of macromolecules from a solution thereof include a) crystallization wherein the target solution and a precipitant are brought into contact in a capillary device and the liquids are mixed solely by diffusion, b) crystallization wherein the target solution and a precipitant are brought into contact or mixed together in a well—i.e. the mixing may be both physical and by diffusion, and c) crystallization wherein the target solution and a precipitant are kept physically separated but in vapor communication with one another. Because of the different nature of the macromolecules the various types of crystallization methods work with a different success rate for different types of macromolecules.

The present invention relates to a method of producing a microfluidic device for use primarily in the type a) crystallization method above, however the microfluidic device produced using the method may also be used in the type crystallization method above.

Examples of prior art microfluidic device for promoting target crystallization are described in WO 2008 000276 and U.S. Pat. No. 6,409,832.

Microfluidic devices adapted for capillary filling with liquids have for many years been produced using general photolithographic methods, such as those traditionally used in the silicon fabrication technology, for example as described in U.S. Pat. No. 6,444,138.

In recent years such capillary microfluidic devices have been produced in polymeric materials e.g. by molding a first substrate with an open channel-shaped cavity and covering this open channel-shaped cavity with a lid having the desired openings for introducing liquids and allowing air to escape as the liquid flow progresses in the formed channel.

In general, it is desired to have high control of a capillary liquid flow in a flow channel, and in particular it is important that creations of unintended air pockets, non-wetted surface sections and similar are avoided.

The present invention provides a novel method for producing microfluidic devices which is particularly useful for crystallization of target molecules using a precipitation liquid.

By using the method of the invention it has also been found that a novel and highly beneficial microfluidic device for crystallization of target molecules can be produced in a very cost effective manner.

Furthermore, by the method of the invention, a microfluidic device for crystallization of target molecules can be produced in a simple way in materials which until the present invention have been difficult to use in the production of microfluidic devices.

The invention and embodiments thereof are defined in the claims. As it will be explained below, the invention and embodiments of the invention exhibit further beneficial properties compared with prior art crystallization devices and methods.

### DISCLOSURE OF INVENTION

The method of the invention for producing a microfluidic device for promoting crystallization of target molecules comprises providing a bottom layer, a structure layer and a top layer. The three layers, the bottom layer, the structure layer and the top layer, are essentially plane layers of solid material and each of the bottom layer, the structure layer and the top layer have a first and a second side.

By the term the three layers are essentially plane is meant that their respective first and second sides are plane on a macroscopic level.

The terms the bottom layer and the top layer should not be interpreted so that the top layer must be on top of the structure layer and the bottom layer must be below the structure layer. Since the path in the microfluidic device has a relatively small cross sectional area, gravity forces are irrelevant or almost irrelevant and the microfluidic device may be turned upside down without any deteriorative effect once the liquids has been feed to the device. The terms the bottom layer and the top layer are used merely to mean that the two layers should be on either sides of the structure layer.

Preferably at least one of the layers, the bottom layer, the structure layer and the top layer, has a uniform thickness, i.e. its first and its second surface are substantially parallel. Preferably all of the three layers have uniform thickness which, however, may be equal or different from each other. In one embodiment the bottom layer has a uniform thickness which is larger than the thickness of the top layer and optionally larger than the thickness of the structure layer. In one embodiment the structure layer has a uniform thickness which is larger than the thickness of the top layer and optionally larger than the thickness of the bottom layer. In one embodiment all of the three layers, the bottom layer, the structure layer and the top layer, have essentially identical uniform thicknesses. In one embodiment the top layer has a uniform thickness which is less than both the thickness of the substrate layer and the bottom layer.

The bottom layer, the structure layer and the top layer may have any peripheral shape. The bottom layer, the structure layer and the top layer may have similar or different peripheral shapes. For simplifying the fixing of the layers to each other in a correct position the bottom layer, the structure layer and the top layer may in one embodiment have similar peripheral shapes. In another embodiment the bottom layer, the structure layer and the top layer have different peripheral shapes and/or sizes and at least one of the layers comprises position markings for simple positioning of one or more of the other layers. As the skilled person will realize there are many different kinds of position markings which may be used e.g. simple color markings and/or protruding flanges.

The peripheral shape of one or more of the bottom layer, the structure layer and the top layer may for example be triangular, rectangular, square, oval, round, pentagonal, hexagonal or any other desirable shape.

The method comprises providing the structure layer with a path shaped through going hole, having a path length and extending from a first path end to a second path end.

The path shaped through going hole may in principle have any size. In general It is preferred that at least one of the thickness of the substrate layer and the width of the path shaped through going hole is about 1000 μm or less, such as about 500 μm or less, for example between about 400 μm and about 25 μm. In principle the thickness of the substrate layer and/or the width of the path shaped through going hole may be even smaller than about 25 μm, but for practical reasons it may be expensive to produce it to be smaller because the requirement to the positioning of the structure layer relative to the bottom layer and/or relative to the top layer may be high. However, in one embodiment at least one of the thickness of the substrate layer and the width of the path shaped through going hole is down to about 5 μm.

In one embodiment the path shaped through going hole has an average width along its length between the path access which is of capillary size, preferably about 500 μm or less, such as about 400 μm or less, such as about 300 μm or less.

The phrase the path shaped through going hole has an average width along its length between the path access which is of capillary size means that the path shaped through going hole has an average width along its length between its path access which when the structure layer is sandwiched between the bottom layer and the top layer is sufficiently small to provide a capillary effect towards water at 20° C.

In one embodiment the structure layer has a thickness which is of capillary size, i.e. the structure layer has a thickness which is sufficiently small so that a capillary effect is provided towards water at 20° C., when the structure layer is sandwiched between the bottom layer and the top layer.

In one embodiment the structure layer has a thickness of about 500 μm or less, such as about 400 μm or less, such as about 300 μm or less. In one embodiment the path shaped through going hole has an average width along its length between the first ant the second path access or at least between its path access (described further below) which is substantially larger than the thickness of the structure layer, the average width optionally being up to about 5 mm, such as up to about 3 mm, such as from about 300 μm to about 500 μm.

The path shaped through going hole may in one embodiment extend along a substantially straight line.

In another embodiment the path length of the path shaped through going hole extends along a curved line.

In one embodiment the path length of the path shaped through going hole comprises at least one straight section and at least one curved section.

In one embodiment the path shaped through going hole comprises one or more branches. In another embodiment the path shaped through going hole is free of branches.

The path shaped through going hole may have any length, but in most situations a total length, including optionally branches, of up to about 500 mm is sufficient. For example the total length of the path shaped through going hole including optional branches is from about 10 mm to about 400 mm, such as from about 20 mm to about 200 mm.

The length of the through going hole means the total length, whereas the length of the through going hole between its path access means the length along the through going hole from a first path access to a second path access.

The method of the invention comprises providing the top layer with a pair of through going inlet holes placed at an inlet hole distance from each other. The pair of through going inlet holes should preferably be arranged such that when the top layer is fixed to the structure layer they mate with the path shaped through going hole to provide access thereto. In one embodiment the method of the invention comprises providing the top layer with three or more through going inlet holes placed at an inlet hole distance from each other, which three or more through going inlet holes are arranged such that when the top layer is fixed to the structure layer they mate with the path shaped through going hole to provide access thereto.

The term path access means a point along the through going hole of the structure layer which is adapted to mate with an access hole of the top layer.

In one embodiment the path shaped through going hole has an average width along its length between the path access which is at least about 5 times smaller than the inlet hole distance, such as at least about 10 times smaller than the inlet hole distance, such as at least about 15 times smaller than the inlet hole distance.

In one embodiment the path access is substantially coincident with respectively the first and the second path ends.

The through going inlet holes may have any sizes and any shapes. In one embodiment at least one, preferably at least two of the through going inlet holes individually of each other have a shape which is triangular, rectangular, square, oval, round, pentagonal or hexagonal. The through going inlet holes may for example individually from each other have a size of from about 1 mm² to about 2 cm², such as from 10 mm² to about 100 mm².

The method of the invention comprises fixing the second side of the bottom layer to the first side of the structure layer and fixing the first side of the top layer to the second side of the structure layer such that the pair of through going inlet holes of the top layer provides access at path access to the path shaped through going hole of the structure layer.

The layers, the bottom layer, the structure layer and the top layer, may be fixed in a sandwich structure using any method including chemical, physical and/or mechanical methods. In one embodiment the layers are fixed in the sandwich structure by a method comprising clamping the layers mechanically. In one embodiment the layers are fixed in the sandwich structure by a method comprising a physical adherence between the layers. In one embodiment the layers are fixed in the sandwich structure by a method comprising chemically bonding the layers. Different desirable methods of fixing the layers are described further below.

In a desirable embodiment of the invention the method comprises providing the second side of the bottom layer with a flow barrier line prior to fixing the second side of the bottom layer to the first side of the structure layer. The flow barrier line should preferably be arranged on the second side of the bottom layer so that the flow barrier line will cross the path shaped through going hole of the structure layer when the second side of the bottom layer has been fixed to the first side of the structure layer.

The flow barrier line may be any kind of elongate structure with a length which is sufficiently long to cross the through going hole of the structure layer when the second side of the bottom layer has been fixed to the first side of the structure layer, and which flow barrier line will provide a flow obstacle for water flowing along the path in the final microfluidic device. The obstacle may be a permanent or a temporary obstacle and it may be an obstacle which completely stops the flow or it may merely delay and/or reduce the flow velocity.

In the produced microfluidic device the flow barrier line will provide a very beneficial feature which will make the microfluidic device particularly simple to use for crystallization of target molecules by using a precipitant liquid. By using such microfluidic device of the invention comprising a flow barrier line, a solution of the target molecule may be introduced into the path via a first access hole, the solution of the target molecule will by capillary forces flow to the crossing flow barrier line, where it will be stopped or be delayed, simultaneously or there after a precipitant liquid can be introduced into the path via a second path access where it will be brought close to or into contact with the solution of the target molecule. The precipitant may flow into the path provided adequate air escape opening(s) is/are provided to allow air (or other gas in the path) to be oust. Such air may e.g. be ousting via a branch channel. As the skilled person will appreciate the order of adding the target solution and the precipitant liquid may be reversed. Examples of precipitant liquids and target solutions may be found in WO 2008 000276 hereby incorporated by reference.

In principle the flow barrier line may be arranged on the second side of the bottom layer so that it will cross the path shaped through going hole of the structure layer at any position along the length of the path shaped through going hole when the second side of the bottom layer has been fixed to the first side of the structure layer.

In one embodiment the flow barrier line is arranged on the second side of the bottom layer so that it will cross the path shaped through going hole of the structure layer at a distance to any of the path access when the second side of the bottom layer has been fixed to the first side of the structure layer. In this embodiment the solution of target molecule and the precipitant liquid can be brought close to each other or into contact in a very simple manner as shown in the examples.

In one embodiment the flow barrier line is arranged on the second side of the bottom layer so that it will cross the path shaped through going hole of the structure layer immediately adjacent to one of the path access when the second side of the bottom layer has been fixed to the first side of the structure layer. In this embodiment the solution of target molecule and the precipitant liquid can be brought close to each other or into contact in a very simple manner as shown in the examples.

In one embodiment the flow barrier line has a length and a width, and the width is preferably at least about 1 μm, such as at least about 5 μm, such as at least about 100 μm, such as up to about 2 mm. The optimal width may be selected in accordance to the desired size of the obstacle, the capillary pull arranged to be provided in a liquid flowing in the path and the kind of flow barrier line provided.

In one embodiment the flow barrier line is in the form of a low surface tension line and/or an indentation.

In one embodiment the liquid barrier line is or comprises a low tension surface barrier line, which means that the surface tension of the flow barrier line on the second side of the bottom layer is substantially lower than the surface tension of the second side of the bottom layer adjacent to the flow barrier line thereon.

In one embodiment the flow barrier line is a low surface tension line, wherein the surface tension along the flow barrier line is substantially lower than the surface tension of the second surface of the bottom layer adjacent to the flow barrier line. In one embodiment the surface tension along the flow barrier line is at least about 5 mN/m, such as at least about 10 mN/m, such as between about 15 mN/m and about 60 mN/m lower than the surface tension of the second surface of the bottom layer adjacent to the flow barrier line.

In one embodiment the surface tension along the flow barrier line is between about 10 mN/m and about 60 mN/m, such as between about 25 mN/m and about 35 mN/m.

Surface tension may e.g. be measured using contact angle. For a surface with a surface tension of less than about 73 mN/m, the contact angle to water is at least about 90 degrees measured in air at 20° C. All measurements are performed in air and at 20° C. and at atmospheric pressure unless anything else is mentioned.

The surface energy and the surface tension are two terms covering the same property of a surface and in general these terms are used interchangeably. The surface energy of a surface may be measured using a tensiometer, such as a SVT 20, Spinning drop video tensiometer marketed by DataPhysics Instruments GmbH. In this application the term surface tension is the macroscopic surface energy, i.e. it is directly proportional to the hydrophilic character of a surface which may e.g. be measured by contact angle to a drop of water as it is well known to the skilled person. In comparing measurements, e.g. when measuring which of two surface parts has the higher surface energy, it is not necessary to know the exact surface energy and it may be sufficient to simply compare which of the two surfaces has the lower contact angle to water.

In one embodiment the flow barrier line is in the form of or comprises an indentation.

In principle the indentation may have any shape and depth as long as it provides an obstacle for liquid to pass the flow barrier line when flowing along the path in the microfluidic device. Generally an indentation with a sharp edge e.g. about 145 degrees or less provides a capillary breach. This effect is well known to the skilled person and he will without unduly effort be able to provide an indentation which provides the desired barrier effect.

The indentation comprises preferably a pair of border edges along its length where the width of the flow barrier line is defined by the distance between the border edges. In one embodiment the indentation comprises at least one relatively sharp border edge preferably with an angle of about 145 degrees or less, the indentation preferably being in the form of a V shaped notch.

In one embodiment the pair of border edges include a first and a second border edge wherein the first border edge is closer to a patch access than the second border edge, the first border edge preferably has an angle of about 145 degrees or less along its length, the first border edge preferably has an angle along its length which is less than the angle of the second border edge.

The flow barrier line may for example be provided by a plasma deposition treatment, a vapor deposition treatment and/or by laser cutting.

One embodiment of the method comprises
providing the structure layer with a plurality of path shaped through going holes, each having a path length and extending from a first path end to a second path end;
providing the top layer with a plurality of pairs of through going inlet holes placed at an inlet hole distance from each other;
fixing the first side of the top layer to the second side of the structure layer such that each pair of through going inlet holes of the top layer provide path access to one of the path shaped through going holes of the structure layer.

The plurality of path shaped through going holes may in principle be identical or different from each other, they may be straight, curved or comprise both straight and curved segments. In one embodiment the plurality of path shaped through going holes are arranged non-systematically. In one embodiment the plurality of path shaped through going holes are arranged substantially systematically. In one embodiment the plurality of path shaped through going holes comprise at least one straight section or they are substantially straight and they are arranged substantially parallel to each other.

According to the method of the invention at least one of the bottom layer and the top layer is of a transparent material. Since the bottom layer and the top layer can be provided in a very simple manner these layers may be provided to have a very high transparency and also they may be provided in materials, including transparent materials which hereforto have been difficult to use in the production of microfluidic devices.

Due to the transparency of at least one of the bottom layer and the top layer, the crystallized molecules obtained when using the provided microfluidic device need not being harvested for performing an analysis of the crystal structure and damage related to handling of the crystals is therefore avoided using the microfluidic device obtainable by the method of the invention because it allows the crystallized molecules to be analyzed in situ in the microfluidic device.

The one or more of the bottom layer, the structure layer and the top layer should in one embodiment be transparent to electromagnetic waves of at least one wavelength. In principle this one or more wavelengths to which one or more of the bottom layer, the structure layer and the top layer are transparent may be any wavelength. In a preferred embodiment one or more of the bottom layer, the structure layer and the top layer are transparent to at least one wavelength selected from Infrared light (about 700 nm to about 1000 μm), visible light (about 400 nm to about 700 nm), UV light (about 400 nm to about 10 nm) about and X-ray light (about 10 nm to about 0.01 nm). In a preferred embodiment one or more of the bottom layer, the structure layer and the top layer are transparent to a range of wavelengths. In one embodiment of the invention one or more of the bottom layer, the structure layer and the top layer are transparent to a range of wavelengths in the short range area, such as a range of wavelengths selected from the wavelength from about 0.01 nm to about 700 nm. By using short wave light for the analysis, the analysis of the crystallized structure of the target molecule can be very detailed and the degrading of the crystal due to heat generation is very small, if any at all.

The bottom layer, the structure layer and the top layer may be provided in the same material or they may be made from different materials. Examples of materials which may be used for the bottom layer, the structure layer and/or the top layer include materials selected from glass and polymer, preferably polymers selected from cyclic oleofin copolymers (COC), acrylonitrile-butadiene-styrene copolymer, polycarbonate, polydimethyl-siloxane (PDMS), polyethylene (PE), polymethylmethacrylate (PMMA), polymethylpentene, polypropylene, polystyrene, polysulfone, polytetra-fluoroethylene (PTFE), polyurethane (PU), polyvinylchloride (PVC), polyvinylidene chloride (PVDC), polyvinylidine fluoride, styrene-acryl copolymers polyisoprene, polybutadiene, polychloroprene, polyisobutylene, poly(styrene-butadiene-styrene), silicones, epoxy resins, Poly ether block amide, polyester, acrylonitrile butadiene styrene (ABS), acrylic, celluloid, cellulose acetate, ethylene-vinyl acetate (EVA), ethylene vinyl alcohol (EVAL), fluoroplastics, polyacetal (POM), polyacrylates (acrylic), polyacrylonitrile (PAN) polyamide (PA), polyamide-imide (PAI), polyaryletherketone (PAEK), polybutadiene (PBD), polybutylene (PB), polybutylene terephthalate (PBT), polyethylene terephthalate (PET), polycyclohexylene dimethylene terephthalate (PCT), polyketone (PK), polyester/polythene/polyethene, polyetheretherketone (PEEK), polyetherimide (PEI), polyethersulfone (PES), polyethylenechlorinates (PEC), polyimide (PI), polylactic acid (PLA), polymethylpentene (PMP), polyphenylene oxide (PPO), polyphenylene sulfide (PPS), polyphthalamide (PPA), and mixtures thereof.

It has been found that when using an X-ray transparent material for at least one of the bottom layer and the top layer it will be extremely simple to observe and analyze the crystallized structure of a target molecule in the microfluidic device without harvesting. By using X-ray for analyzing the crystallized structure of a target molecule a very detailed analysis can be obtained without any substantial damage of the crystallized molecule.

In one embodiment of the invention at least the cover is made from an X-ray transparent material, preferably a polyimide, e.g. a phenylene-pyromellitimide such as poly(4,4′-oxodiphenylene-pyromellitimide e.g. Kapton®. The cover may in this embodiment for example be of a film of the X-ray transparent material.

In one embodiment one or more, such as all of the bottom layer, structure layer and top layer are made from an x-ray transparent material, preferably a polyimide, e.g. a phenylene-pyromellitimide such as poly(4,4′-oxodiphenylene-pyromellitimide e.g. Kapton®.

In one embodiment the bottom layer and the top layer are made from an x-ray transparent material, the structure layer optionally being made from a non-x-ray transparent material.

Generally such x-ray transparent material is very difficult to provide with complex shapes. However, by using the method of the invention the individual layers can be provided in such x-ray transparent material in a simple manner, even when such material cannot be provided by molding, e.g. injection molding. The structure layer may for example by provided in an x-ray transparent material by cutting the path shaped through going holes by a laser, by cutting or by stamping out. The other layers may be provided in a similar manner.

One or both of the first and the second surfaces of the respective layers may for example be subjected to a surface treatment, e.g. a surface treatment for altering the surface tension. In one embodiment only a part of one or both of the first and the second surfaces of the respective layers may for example be subjected to a surface treatment, the remaining part being covered during the treatment.

In one embodiment at least a part of the second side of the first layer and the first side of the third layer are treated to increase the surface tension, the treatment preferably being a plasma treatment, a corona treatment or a vapor deposition treatment.

In one embodiment the method comprises fixing the second side of the bottom layer to the first side of the structure layer and fixing the first side of the top layer to the second side of the structure layer, wherein the fixing of layers is performed simultaneously or one after the other, preferably at least one of the fixing being performed by use of one or more of laser bonding, adhesive bonding, plasma bonding and mechanical fixing.

In one embodiment the fixing of layers is performed by a method using plasma bonding, the plasma bonding preferably being a oxygen plasma bonding.

Plasma bonding techniques are generally known to the skilled person. In one embodiment the method comprises exposing both bonding surfaces to an oxygen plasma for a sufficient time e.g. 1 minute or more, and immediately there after bringing them in intimate contact with each other. The plasma treatment makes the surfaces extremely clean, which facilitates the bonding process.

In one embodiment the method comprises providing the bottom layer, the structure layer and the top layer of an x-ray transparent material, and bonding the layers to each other using plasma bonding.

The invention also relates to a microfluidic device for promoting crystallization of target molecules obtainable by the method as claimed by any one of the preceding claims.

The device of the invention for promoting crystallization of target molecules has thus shown to be very economical compared with prior art devices. One reason for this is that it is inexpensive to produce and simultaneously very simple, fast and reliable in use.

The term for promoting crystallization of target molecules includes both the formation of the first crystals (crystal germs), as well as further growing of crystals. For some tests it is desired to examine small crystals, for other tests it may be desired to allow the crystal growth to proceed until larger crystals are formed.

In a preferred embodiment the microfluidic device of the invention comprises at least one flow barrier line.

### BRIEF DESCRIPTION OF DRAWINGS AND EXAMPLES

Embodiments of the invention will be described more fully below and with reference to the drawings and examples in which:

FIGS. 1a and 1b are schematic drawings of a first embodiment of the invention illustrating the bottom layer, the structure layer and the top layer separate from each other and fixed to each other, respectively.

FIGS. 2a and 2b are schematic drawings of a second embodiment of the invention illustrating the bottom layer, the structure layer and the top layer separate from each other and fixed to each other, respectively.

FIGS. 3a and 3b are schematic drawings of a third embodiment of the invention illustrating the bottom layer, the structure layer and the top layer separate from each other and fixed to each other, respectively.

FIGS. 4a and 4b are schematic drawings of a fourth embodiment of the invention illustrating the bottom layer, the structure layer and the top layer separate from each other and fixed to each other, respectively.

FIGS. 5a and 5b are schematic drawings of a fifth embodiment of the invention illustrating the bottom layer, the structure layer and the top layer separate from each other and fixed to each other, respectively.

FIGS. 6a and 6b are schematic drawings of a sixth embodiment of the invention illustrating the bottom layer, the structure layer and the top layer separate from each other and fixed to each other, respectively.

FIGS. 7a and 7b are schematic drawings of a seventh embodiment of the invention illustrating the bottom layer, the structure layer and the top layer separate from each other and fixed to each other, respectively.

FIGS. 8a and 8b are schematic drawings of an eighth embodiment of the invention illustrating the bottom layer, the structure layer and the top layer separate from each other and fixed to each other, respectively.

FIGS. 9, 10 and 11 are schematic drawings of cross sectional side views of different bottom layers comprising a flow barrier line.

The figures are schematic and simplified for clarity and just show details which are essential to the understanding of the invention, while other details are left out. Throughout, the same reference numerals are used for identical or corresponding parts.

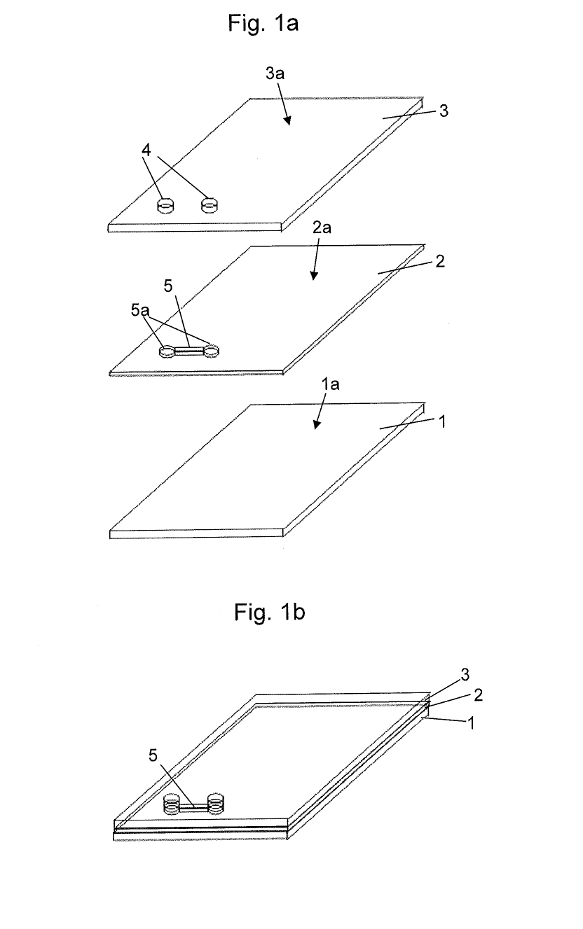

FIG. 1a shows the bottom layer 1, the structure layer 2 and the top layer 3 of a first embodiment of the invention. The 3 layers 1, 2, 3 may for example have been produced from plates of the same or different materials, wherefrom the layers with rectangular periphery are cut or pressed out. Simultaneously with the cutting/pressing out of the layers 1, 2, 3, the structure layer 2 and the top layer 3 may be provided with respectively through going inlet holes 4 and a path shaped through going hole 5.

The layers 1, 2, 3 as well as the through going inlet holes 4 and a path shaped through going hole 5 are provided using a laser cutter.

The laser used for performing the laser cutting can in principle be any kind of laser which emits a laser beam with a sufficient power to cut through the respective layers. In one embodiment an infra red laser cutter is used, such as a CO₂ laser. In one embodiment a neodymium laser is used.

The layers 1, 2, 3 as well as the through going inlet holes 4 and a path shaped through going hole 5 are provided using mechanical cutting.

The through going inlet holes 4 are essentially round. They could have any other shape, but for simplification it is often desired to make them circular or oval.

The path shaped through going hole 5 is essentially straight and has an enlargement 5a in its first and its second end. These enlargements 5a are provided to mate with the respective through going inlet holes 4.

The bottom layer 1, the structure layer 2 and the top layer 3 have each a not shown first side and a second opposite side 1a, 2a, 3a.

After the bottom layer 1, the structure layer 2 and the top layer 3 have been cut, the three layers 1, 2, 3 are arranged in a plasma chamber in such a way that the first side of the top layer 3, the second side 1a of the bottom layer 1 and most of both of the sides 1a of the structure layer 2 are capable of being subjected to a plasma.

An oxygen plasma, preferably a low pressure oxygen plasma, such as an RF coil oxygen plasma at about 65 mbar, is turned on for about 2 minutes, where after the plasma is turned off and the three layers 1, 2, 3 are removed from the plasma chamber. The three layers 1, 2, 3 are there after applied onto each other as shown in FIG. 1b and pressed together for about one hour. The three layers should now be fixed to each other.

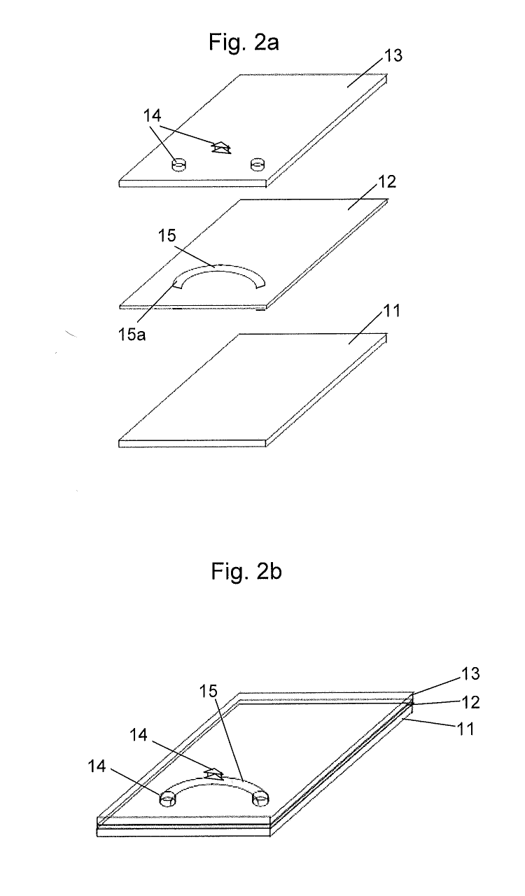

FIGS. 2a and 2b show a second embodiment which differs from the embodiment shown in FIGS. 1a and 1b in that the path shaped through going hole 15 is curved and that the top layer 13 comprises three through going inlet holes 14. Furthermore the structure layer 12 is slightly larger than the bottom layer 11 and the top layer 13.

FIG. 2a shows the bottom layer 11, the structure layer 12 and the top layer 13 which may be produced as described above. The top layer 13 is provided with three through going inlet holes 14 which may have equal size and shape or they may differ in size and/or shapes. The structure layer is provided with a curved path shaped through going hole 15, with a first and a second end 15a which each is adapted to mate with one of the through going inlet holes 14 to provide access to path access when the three layers 11, 12, 13 are fixed to each other. The third of the three through going inlet holes 14 is adapted to provide a third path access to the path at a point along the path, in the shown embodiment about the middle of the path.

The bottom layer 11, the structure layer 12 and the top layer 13 have each a not shown first side and a second opposite side 11a, 12a, 13a.

After the bottom layer 11, the structure layer 12 and the top layer 13 have been cut, the three layers 11, 12, 13 are arranged in a plasma chamber in such a way that the first side of the top layer 3, the second side 1a of the bottom layer 1 and most of both of the sides 1a, except the part of both of the sides 1a which are not adapted to be fixed to respectively the top layer 13 and the bottom layer 11 of the structure layer 2, are capable of being subjected to a plasma.

The fixing is performed as described above.

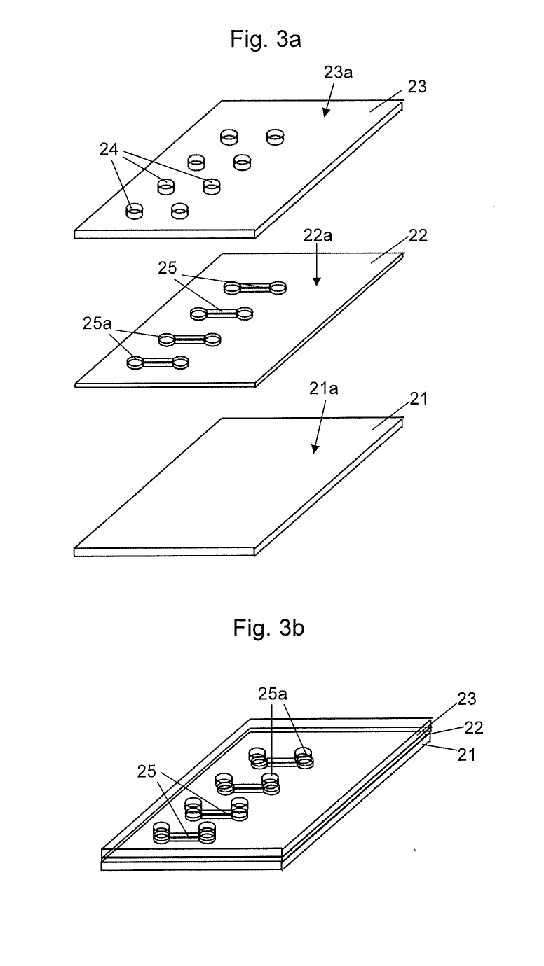

FIGS. 3a and 3b show a third embodiment which differs from the embodiment shown in FIGS. 1a and 1b in that the top layer 23 and the structure layer 22 are provided with a plurality of respectively path shaped through going holes 25 and pair wise through going inlet holes 24.

FIG. 3a shows the bottom layer 21, the structure layer 22 and the top layer 23 of a third embodiment of the invention. The top layer 23 is provided with a plurality of pair wise through going inlet holes 24 and the structure layer is provided with a plurality of substantially straight, path shaped through going holes 25, each with a first and a second end 25a, which each is adapted to mate with one of the through going inlet holes 24 to provide access to path access when the three layers 21, 22, 23 are fixed to each other.

The bottom layer 21, the structure layer 22 and the top layer 23 have each a not shown first side and a second opposite side 21a, 22a, 23a.

After the bottom layer 21, the structure layer 22 and the top layer 23 have been cut, the three layers 21, 22, 23 are melted to each other by pressing them together under raised temperature. Alternatively the three layers 21, 22, 23 may be fixed using plasma bonding as described above.

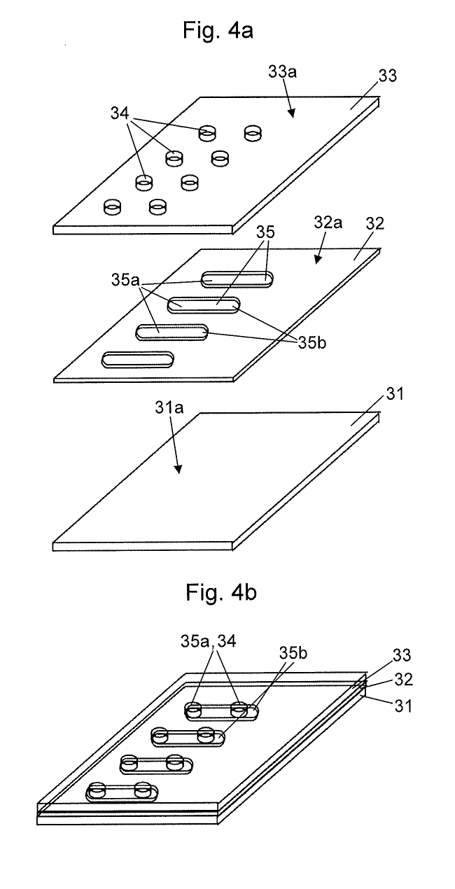

FIGS. 4a and 4b show a third embodiment which differs from the embodiment shown in FIGS. 3a and 3b in that the path shaped through going holes 35 in the structure layer 32 have a slightly different shape.

FIG. 4a shows the bottom layer 31, the structure layer 32 and the top layer 33 of a fourth embodiment of the invention. The top layer 33 is provided with a plurality of pair wise through going inlet holes 34 and the structure layer is provided with a plurality of substantially straight, path shaped through going holes 35, each with a first end 35a and a second end 35b. The first end 35a is adapted to mate with one of the through going inlet holes 34, whereas the other one of the pair wise through going holes 34 is adapted to provide a path access to the path at a distance of the second end 35b.

The bottom layer 31, the structure layer 32 and the top layer 33 have each a not shown first side and a second opposite side 31a, 32a, 33a. The three layers are fixed to each other as described above.

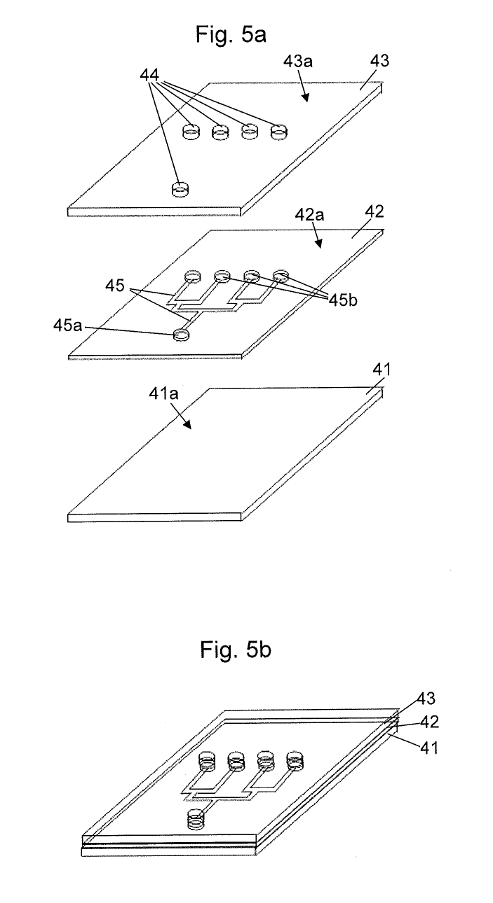

FIGS. 5a and 5b show a second embodiment which differs from the embodiment shown in FIGS. 1a and 1b in that the path shaped through going hole 45 is branched and that the top layer 13 comprises five through going inlet holes 44.

FIG. 5a shows the bottom layer 41, the structure layer 42 and the top layer 43 which may be produced as described above. The top layer 43 is provided with five through going inlet holes 44 which may have equal size and shape or they may differ in size and/or shapes. The structure layer is provided with a branched path shaped through going hole 45, with a first end 45a and four second ends 45b. Each of the first and the second ends 45a, 45b are adapted to mate with one of the through going inlet holes 44 to provide access to path access when the three layers 41, 42, 43 are fixed to each other.

The bottom layer 41, the structure layer 42 and the top layer 43 have each a not shown first side and a second opposite side 41a, 42a, 43a. The layers 41, 42, 43 may be fixed to each other using the methods described above.

In use a target molecule solution may for example be applied in the first end 45a, and different or equal precipitant liquids may be applied in the second ends 45b.

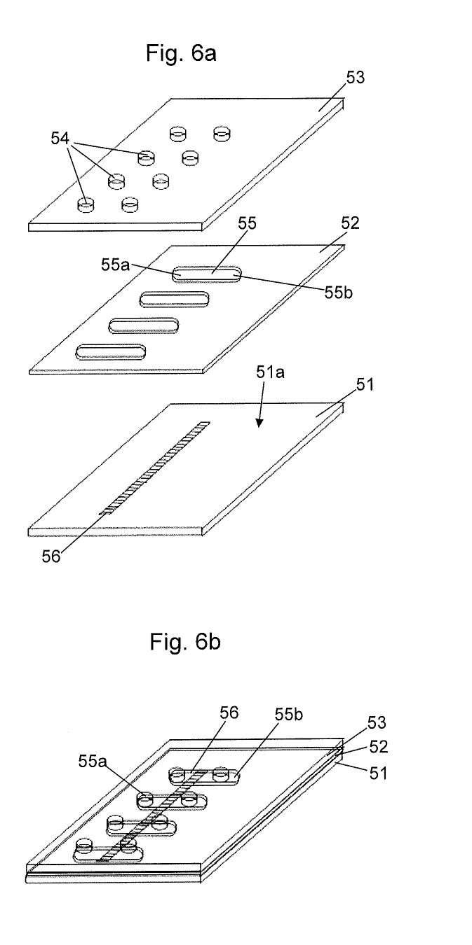

FIGS. 6a and 6b show a third embodiment which differs from the embodiment shown in FIGS. 4a and 4b in that the bottom layer 51 further is provided with a flow barrier line 56.

FIG. 6a shows the bottom layer 51, the structure layer 52 and the top layer 53 of a sixth embodiment of the invention. The top layer 53 is provided with a plurality of pair wise through going inlet holes 54 and the structure layer is provided with a plurality of substantially straight, path shaped through going holes 55, each with a first end 55a and a second end 55b. The first end 55a is adapted to mate with one of the through going inlet holes 54, whereas the other one of the pair wise through going holes 54 is adapted to provide a path access to the path at a distance of the second end 55b.

The bottom layer 51 is provided with a flow barrier line 56 which is in the form of a line on the second surface 51a of the bottom layer 51, which line has a width and a length in which the surface tension is lower than the remaining surface tension of the second surface 51a of the bottom layer 51.

The flow barrier line 56 is arranged on the second surface 51a of the bottom layer 51 so that the flow barrier line 56 will cross the path shaped through going holes 55 when the three layers 51, 52, 53 are fixed to each other. In the shown embodiment the flow barrier line 56 is arranged on the second surface 51a of the bottom layer 51 so that it will cross the path shaped through going holes 55 at a distance from their path access provided by the plurality of pair wise through going inlet holes 54.

The three layers are fixed to each other as described above.

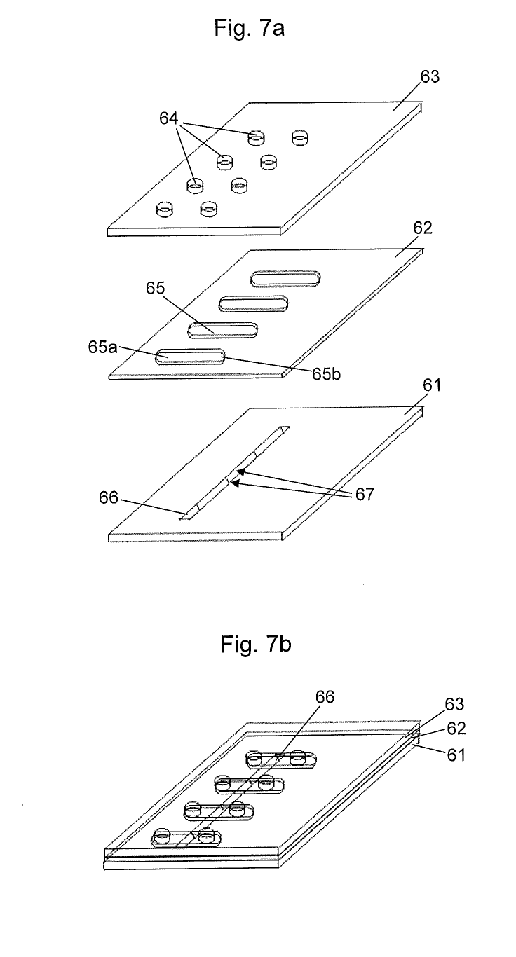

FIGS. 7a and 7b show a third embodiment which differ from the embodiment shown in FIGS. 6a and 6b in that the bottom layer 61 further is provided with another type of flow barrier line 66.

FIG. 7a shows the bottom layer 61, the structure layer 62 and the top layer 63 of a seventh embodiment of the invention. The top layer 63 is provided with a plurality of pair wise through going inlet holes 64 and the structure layer is provided with a plurality of substantially straight, path shaped through going holes 65, each with a first end 65a and a second end 65b. The first end 65a is adapted to mate with one of the through going inlet holes 64, whereas the other one of the pair wise through going holes 64 is adapted to provide a path access to the path at a distance of the second end 65b.

The bottom layer 61 is provided with a flow barrier line 66 which is in the form of a V shaped notch on the second surface 61a of the bottom layer 61, which V shaped notch has a width and a length, the width is the distance between the pair of border edges 67 provided by the V shaped notch. The pair of border edges 67 includes a first and a second border edge 67 wherein the first border edge is closer to a patch access than the second border edge, the first border edge preferably has an angle of about 145 degrees or less along its length.

The flow barrier line 66 is arranged in the second surface 61a of the bottom layer 61 so that the flow barrier line 66 will cross the path shaped through going holes 65 when the three layers 61, 62, 63 are fixed to each other. In the shown embodiment the flow barrier line 56 is arranged on the second surface 61a of the bottom layer 61 so that it will cross the path shaped through going holes 65 at a distance from their path access provided by the plurality of pair wise through going inlet holes 64.

The three layers are fixed to each other as described above.

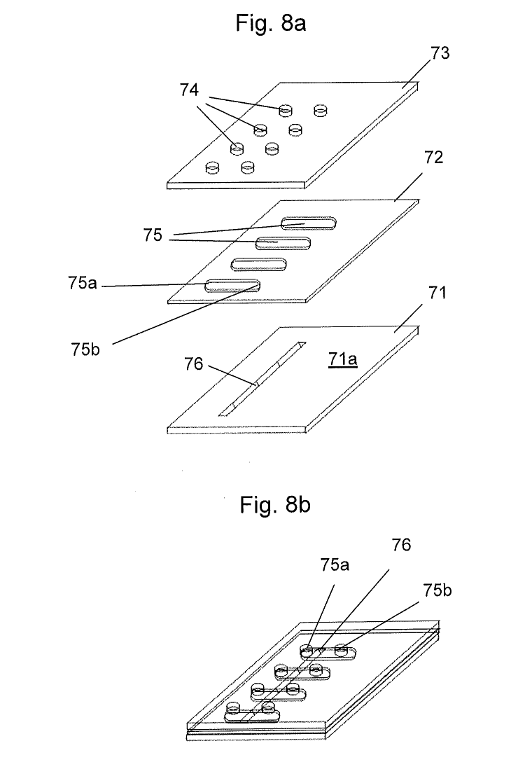

FIGS. 8a and 8b show a third embodiment which differs from the embodiment shown in FIGS. 7a and 7b in that the flow barrier line 76 in bottom layer 71 is arranged such in relation to the path shaped through going holes 75 that it will cross these path shaped through going holes 75 immediately adjacent to the path access when the three layers 71, 72, 73 are fixed to each other.

FIG. 8a shows the bottom layer 71, the structure layer 72 and the top layer 73 of an eighth embodiment of the invention. The top layer 73 is provided with a plurality of pair wise through going inlet holes 74 and the structure layer is provided with a plurality of substantially straight, path shaped through going holes 75, each with a first end 75a and a second end 75b. The first end 75a is adapted to mate with one of the through going inlet holes 74, whereas the other one of the pair wise through going holes 74 is adapted to provide a path access to the path at a distance of the second end 75b.

The bottom layer 71 is provided with a flow barrier line 76 which is in the form of a V shaped notch on the second surface 71a of the bottom layer 71. The flow barrier line 76 is arranged in the second surface 71a of the bottom layer 71 so that the flow barrier line 76 will cross the path shaped through going holes 75 when the three layers 71, 72, 73 are fixed to each other immediately adjacent to one of the path access provided by the plurality of pair wise through going inlet holes 74.

The three layers are fixed to each other as described above.

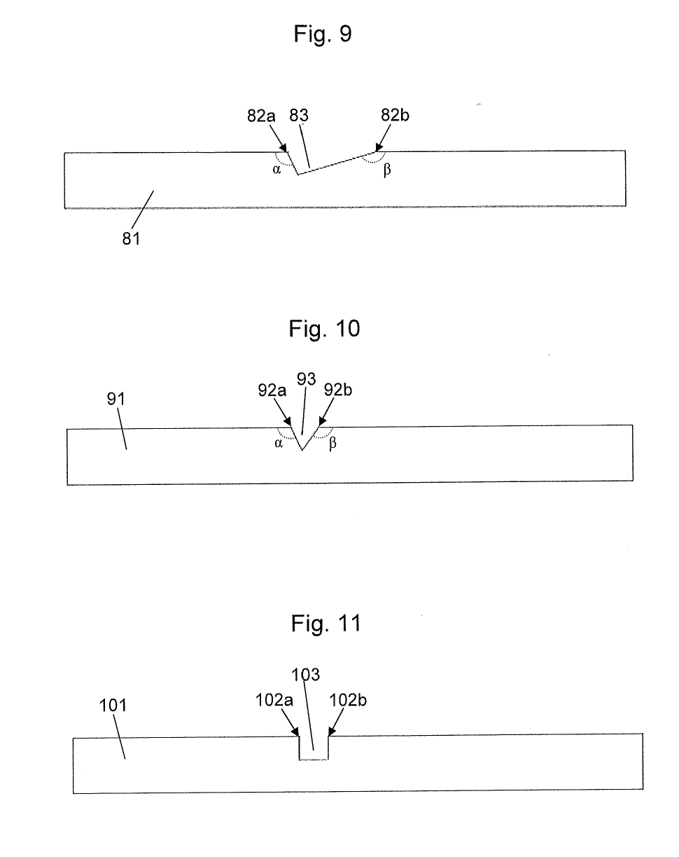

FIG. 9 shows a cross sectional side views of a bottom layer 81 comprising a flow barrier line 83 in the form of an indentation. The flow barrier line 83 comprises a first and a second border edge 82a, 82b. The first border edge 82a has a relatively sharp angle α which is about 100 degrees and the second border edge 82b has a less sharp angle β which is about 165 degrees. When a liquid flows toward the barrier line 83 from its first border edge 82a side, it will stop flowing further when it reaches the first border edge 82a. When a liquid flows toward the barrier line 83 from its second border edge 82b side, it will not be stopped by the second border edge 82b but will flow further and cross the flow barrier line 83.

FIG. 10 shows a cross sectional side view of a bottom layer 91 comprising a flow barrier line 93 in the form of a V-shaped indentation. The flow barrier line 93 comprises a first and a second border edge 92a, 92b. Both of the first and the second border edges 92a, 92b have relatively sharp angles α, β which are about 100 degrees.

FIG. 11 shows a cross sectional side view of a bottom layer 101 comprising a flow barrier line 103 in the form of a U-shaped indentation. The flow barrier line 103 comprises a first and a second border edge 102a, 102b. Both of the first and the second border edges 102a, 102b have relatively sharp angles α, β which are about 100 degrees.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

Some preferred embodiments have been shown in the foregoing, but it should be stressed that the invention is not limited to these, but may be embodied in other ways within the subject-matter defined in the following claims.

1. A method of producing a microfluidic device for promoting crystallization of target molecules, said method comprising
providing a bottom layer, a structure layer and a top layer, said bottom layer, structure layer and top layer being essentially plane layers of solid material, each of said bottom layer, structure layer and top layer having a first and a second side;
providing said structure layer with a path shaped through going hole, having a path length and extending from a first path end to a second path end;
providing said top layer with a pair of through going inlet holes placed at an inlet hole distance from each other;
fixing the second side of the bottom layer to the first side of the structure layer;
fixing the first side of the top layer to the second side of the structure layer such that the pair of through going inlet holes of the top layer provide access at path access to said path shaped through going hole of the structure layer;
wherein at least one of said bottom layer and said top layer is of a transparent material.

2. The method as claimed in claim 1, wherein the path shaped through going hole has an average width along its length between said path access which is at least about 5 times smaller than said inlet hole distance.

3. The method as claimed in claim 1, wherein said path access is substantially coincident with respectively said first and said second path ends.

4. The method as claimed in claim 1, wherein said path shaped through going hole has an average width along its length between said path access which is of capillary size.

5. The method as claimed in claim 1, wherein the structure layer has a thickness of about 500 μm or less.

6. The method as claimed in claim 1, wherein the path length of said path shaped through going hole extends along a substantially straight line.

7. The method as claimed in claim 1, wherein the path length of said path shaped through going hole extends along a curved line.

8. The method as claimed in claim 1, wherein the method comprises providing said second side of said bottom layer with a flow barrier line, said second side of said bottom layer being fixed to said first side of said structure layer so that said flow barrier line is arranged to cross said path shaped through going hole of said structure layer.

9. The method as claimed in claim 8, wherein said second side of said bottom layer is fixed to said first side of said structure layer so that said flow barrier line is arranged to cross said path shaped through going hole of said structure layer immediately adjacent to one of said path access.

10. The method as claimed in claim 8, wherein said flow barrier line has a length and a width, the width preferably being at least about 1 μm.

11. The method as claimed in claim 8, wherein said flow barrier line is a low surface tension line and/or an indentation.

12. The method as claimed in claim 11, wherein said flow barrier line is a low surface tension line, wherein the surface tension along said flow barrier line is substantially lower than the surface tension of the second surface of the bottom layer adjacent to the flow barrier line.

13. The method as claimed in claim 12, wherein the surface tension along said flow barrier line is between about 10 mN/m and about 60 mN/m.

14. The method as claimed in claim 11, wherein said flow barrier line is an indentation comprising a pair of border edges along its length, said indentation comprising at least one relatively sharp border edge with an angle of about 145 degrees or less.

15. The method as claimed in claim 14, wherein said pair of border edges includes a first and a second border edge wherein said first border edge is closer to said path access than said second border edge, said first border edge has an angle of about 145 degrees or less along its length.

16. The method as claimed in claim 11, wherein said flow barrier line is an indentation in the form of a V shaped notch.

17. A method as claimed in claim 1, wherein said structure layer is of a material selected from glass and polymer.

18. The method as claimed in claim 1, wherein one or more, such as all of said bottom layer, structure layer and top layer are made from an x-ray transparent material, preferably a polyimide, e.g. a phenylene-pyromellitimide such as poly(4,4′-oxodiphenylene-pyromellitimide e.g. Kapton®.

19. The method as claimed in claim 18, wherein x-ray transparent material, is a polyimide.

20. The method as claimed in claim 1, wherein at least a part of said second side of said first layer and said first side of said third layer are treated to increase the surface tension.

21. The method as claimed in claim 1, wherein the method comprising fixing the second side of the bottom layer to the first side of the structure layer and fixing said first side of the top layer to the second side of the structure layer, wherein said fixing of layers is performed simultaneously or one after the other.

22. The method as claimed in claim 21 wherein said fixing of layers is performed by use of one or more of laser bonding, adhesive bonding, plasma bonding and mechanical fixing.

23. The method as claimed in claim 1, wherein the method comprises providing said bottom layer, said structure layer and said top layer of an x-ray transparent material, and bonding said layers to each other using plasma bonding.

24. A microfluidic device for promoting crystallization of target molecules obtained by the method as claimed claim 1.

25. A method of producing a microfluidic device for promoting crystallization of target molecules, said method comprising
providing a bottom layer, a structure layer and a top layer, said bottom layer, structure layer and top layer being essentially plane layers of solid material, each of said bottom layer, structure layer and top layer having a first and a second side;
providing said structure layer with a plurality of path shaped through going hole, each having a path length and extending from a first path end to a second path end;
providing said top layer with a plurality of pairs of through going inlet holes placed at an inlet holes distance from each other;
fixing the first side of the top layer to the second side of the structure layer such that each pair of through going inlet holes of the top layer provides access at path access to one of said path shaped through going holes of the structure layer,
wherein at least one of said bottom layer and said top layer is of a transparent material.
